(19) United States
(12) Patent Application Publication
(10) Pub. No.: US 2024/0072173 A1
(43) Pub. Date: Feb. 29, 2024

(54) VERTICAL SEMICONDUCTOR DEVICE WITH BODY CONTACT, METHOD OF MANUFACTURING VERTICAL SEMICONDUCTOR DEVICE WITH BODY CONTACT, AND ELECTRONIC APPARATUS

(71) Applicant: INSTITUTE OF MICROELECTRONICS, CHINESE ACADEMY OF SCIENCES, Beijing (CN)

(72) Inventor: Huilong Zhu, Poughkeepside, NY (US)

(21) Appl. No.: 18/236,788

(22) Filed: Aug. 22, 2023

(30) Foreign Application Priority Data
Aug. 23, 2022 (CN) 202211015632.6

(51) Int. Cl. H01L 29/786; H01L 29/66

(52) U.S. Cl. CPC H01L 29/78615; H01L 29/66742; H01L 29/78618; H01L 29/78642

(57) ABSTRACT

Disclosed are a vertical semiconductor device with a body contact, a manufacturing method, and an electronic apparatus. The semiconductor device includes: an active region vertically disposed on a substrate, including lower and upper source/drain regions, and a middle portion between lower and upper source/drain regions for defining a channel region; a gate stack on a first side of the active region in a lateral direction to at least overlap with the middle portion; and a body contact layer on a second side of the active region opposite to the first side in the lateral direction to overlap with the middle portion to apply a body bias to the active region. In a vertical direction, distances between a part of the middle portion overlapping with the body contact layer and the lower source/drain region and between the part and the upper source/drain region are first and second spacing distances, respectively.

### CROSS REFERENCE TO RELATED APPLICATION

This application claims priority to Chinese Patent Application No. 202211015632.6, filed on Aug. 23, 2022, the entire content of which is incorporated herein in its entirety by reference.

### TECHNICAL FIELD

The present disclosure relates to a field of semiconductors, in particular to a vertical semiconductor device with a body contact, a method of manufacturing the vertical semiconductor device with the body contact, and an electronic apparatus including the semiconductor device.

### BACKGROUND

In order to meet a demand for a continuous miniaturization of a metal oxide semiconductor field effect transistor (MOSFET), various types of devices, such as a fin field effect transistor (FinFET), a multi-bridge channel field effect transistor (MBCFET), etc., have been proposed. However, they still have certain limitations.

A vertical FET is a MOSFET which has a prospect in terms of miniaturization. However, a fully depleted vertical FET has a floating-body effect, which may cause a threshold voltage (Vt) shift and increase an off current. A body contact may be used to suppress the floating-body effect. However, the body contact may increase a channel thickness and degrades a device performance, such as short channel control degradation. At present, it is difficult to fabricate a high-quality body contact on a vertical device.

### SUMMARY

In view of the above, an object of the present disclosure is at least partially to provide a vertical semiconductor device with a body contact, a method of manufacturing the semiconductor device, and an electronic apparatus including the semiconductor device.

According to an aspect of the present disclosure, there is provided a semiconductor device, including: an active region vertically disposed on a substrate with respect to the substrate, wherein the active region includes a lower source/drain region, an upper source/drain region, and a middle portion which is located between the lower source/drain region and the upper source/drain region and configured to define a channel region; a gate stack disposed on a first side of the active region in a lateral direction with respect to the substrate, so as to at least overlap with the middle portion of the active region; and a body contact layer disposed on a second side of the active region opposite to the first side in the lateral direction, so as to overlap with the middle portion of the active region to apply a body bias to the active region, wherein in a vertical direction with respect to the substrate, a distance between a part of the middle portion of the active region overlapping with the body contact layer and the lower source/drain region is a first spacing distance, and a distance between the part of the middle portion of the active region overlapping with the body contact layer and the upper source/drain region is a second spacing distance.

According to another aspect of the present disclosure, there is provided a method of manufacturing a semiconductor device, including: providing, on a substrate, a stack of a first source/drain defining layer, a first channel defining layer, a body contact defining layer, a second channel defining layer, and a second source/drain defining layer; forming an active layer on a vertical sidewall of the stack extending in a first direction; respectively driving a dopant in the first source/drain defining layer, a dopant in the body contact defining layer and a dopant in the second source/drain defining layer into corresponding portions of the active layer, so as to form a lower source/drain region, a body contact region and an upper source/drain region respectively; forming a gate stack on a side of the active layer facing away from the stack in a second direction intersecting the first direction; and forming a body contact portion to the body contact defining layer.

According to another aspect of the present disclosure, there is provided an electronic apparatus, including the semiconductor device described above.

According to embodiments of the present disclosure, the body contact is provided for the vertical semiconductor device, so that the floating-body effect may be suppressed.

### BRIEF DESCRIPTION OF THE DRAWINGS

The above and other objectives, features and advantages of the present disclosure will be more apparent through the following descriptions of embodiments of the present disclosure with reference to the accompanying drawings, in which:

FIG. 1 to FIG. 12 show schematic diagrams of some stages in a process of manufacturing a semiconductor device according to an embodiment of the present disclosure;

FIG. 13 to FIG. 17 show schematic diagrams of some stages in a process of manufacturing a semiconductor device according to another embodiment of the present disclosure.

Throughout the accompanying drawings, the same or similar reference signs indicate the same or similar components.

### DETAILED DESCRIPTION OF EMBODIMENTS

Embodiments of the present disclosure will be described below with reference to the accompanying drawings. It should be understood, however, that these descriptions are merely exemplary and are not intended to limit the scope of the present disclosure. In addition, in the following descriptions, descriptions of well-known structures and technologies are omitted to avoid unnecessarily obscuring the concept of the present disclosure.

Various schematic structural diagrams according to embodiments of the present disclosure are shown in the accompanying drawings. The drawings are not drawn to scale. Some details are enlarged and some details may be omitted for clarity of presentation. Shapes of various regions and layers as well as relative sizes and positional relationships of the various regions and layers shown in the drawings are only exemplary. In practice, there may be deviations due to manufacturing tolerances or technical limitations, and those skilled in the art may additionally design regions/layers with different shapes, sizes, and relative positions according to actual requirements.

In the context of the present disclosure, when a layer/element is referred to as being “on” a further layer/element, the layer/element may be directly on the further layer/element, or there may be an intermediate layer/element between them. In addition, if a layer/element is located “on” a further layer/element in one orientation, the layer/element may be located “under” the further layer/element when the orientation is reversed.

According to embodiments of the present disclosure, a vertical semiconductor device with a body contact is provided. The vertical device may include an active region disposed vertically (for example, in a direction substantially perpendicular to a surface of the substrate) with respect to a substrate, and the active region includes a lower source/drain region disposed at a lower end of the active region and an upper source/drain region disposed at an upper end of the active region. A middle portion between the lower source/drain region and the upper source/drain region in the active region may define a channel region. The lower source/drain region and the upper source/drain region may be electrically connected to each other through the channel region. The lower source/drain region and the upper source/drain region may be defined by a doping region. The channel region may also be doped as needed.

A gate stack may be disposed on a first side of the active region in a lateral direction (substantially parallel to the surface of the substrate), and at least overlaps with the middle portion (or the channel region) of the active region, so as to control the on-off of a conductive channel in the channel region. A body contact layer may be provided on a second side of the active region opposite to the first side. The body contact layer may overlap with the middle portion (or a body portion) of the active region to apply a body bias to the active region. Accordingly, the gate stack may control the on-off of the channel from the first side, while the body contact layer may control a floating-body effect from the second side.

The active region, especially the middle portion of the active region, may be provided with a doping region as a body contact region, and the body contact layer applies the body bias to the active region through the body contact region. The body contact region may only occupy a part of the middle portion of the active region in a vertical direction, and thus has a different doping characteristic from a remaining part of the middle portion of the active region. For example, the remaining part of the middle portion of the active region may not be intentionally doped or have a different doping concentration. As described below, the body contact region may be self-aligned with the body contact layer. For example, the body contact region may be formed by (substantially laterally) driving a dopant into the active region from the body contact layer.

A spacing distance between the body contact layer (and thus the body contact region) and the lower source/drain region and the upper source/drain region in the vertical direction may be adjusted as required. For example, the spacing distance is substantially the same or biased towards the lower source/drain region or the upper source/drain region. As described below, the distance adjustment may be achieved through a film thickness of an epitaxial semiconductor layer, and thus a film thickness accuracy of an epitaxial growth process may be achieved.

The body contact layer may extend laterally, so that the body contact portion used for applying the body bias may be landed on the body contact layer.

Similarly, an upper source/drain region contact layer in contact with the upper source/drain region may be provided on the second side of the active region. The upper source/drain region contact layer may extend laterally, so that an upper source/drain region contact portion used for applying/outputting an electrical signal to/from the upper source/drain region may be landed on the upper source/drain region contact layer. As described below, the upper source/drain region may be self-aligned with the upper source/drain region contact layer. For example, the upper source/drain region may be formed by (substantially laterally) driving a dopant into the active region from the upper source/drain region contact layer.

A spacing between the upper source/drain region contact layer and the body contact layer in the vertical direction may be substantially uniform. As described below, the spacing may be achieved through the film thickness of the epitaxial semiconductor layer, and thus the film thickness accuracy of the epitaxial growth process may be achieved.

The active region may be provided by an active layer of a semiconductor. The active layer may be in a form of a nanosheet or a nanowire, and may include a vertical extension portion extending in the vertical direction to provide the above-mentioned vertical active region. In addition, the active layer may further include a lateral extension portion extending from a lower end of the vertical extension portion (more specifically, the lower source/drain region) away from the vertical extension portion on the first side. The lateral extension portion facilitates the formation of a lower source/drain region contact portion to the lower source/drain region. For example, the lateral extension portion of the active layer may extend beyond the upper gate stack, and the lower source/drain contact portion may be landed thereon.

The active layer may be formed on a lower source/drain region defining layer. The lower source/drain region defining layer may extend from below the lateral extension portion of the active layer to a surface of the vertical extension portion of the active layer on the second side. As described below, the lower source/drain region may be self-aligned with a part of the lower source/drain region defining layer on the second side. For example, the lower source/drain region may be formed by driving a dopant into the active layer from the lower source/drain region defining layer.

A spacing between the lower source/drain region defining layer and the body contact layer in the vertical direction may be substantially uniform. As described below, the spacing may be achieved through the film thickness of the epitaxial semiconductor layer, and thus the film thickness accuracy of the epitaxial growth process may be achieved.

The active layer may be an epitaxial layer on the lower source/drain region defining layer, the body contact layer, and the upper source/drain region contact layer, and thus may have a crystal interface with the lower source/drain region defining layer, the body contact layer, and the upper source/drain region contact layer. These layers may all be single crystal semiconductors.

According to embodiments, the vertical semiconductor device may be manufactured as follows.

A stack of a first source/drain defining layer, a first channel defining layer, a body contact defining layer, a second channel defining layer, and a second source/drain defining layer may be disposed on a substrate. The stack may be formed by an epitaxial growth. Accordingly, a thickness of each layer may be well controlled. Each layer in the stack may be doped in situ during growth to achieve a desired doping characteristic. For example, the first source/drain defining layer and the second source/drain defining layer may be heavily doped to achieve source/drain regions. The body contact layer may be lightly doped to achieve a body contact region. The first channel defining layer and the second channel defining layer may be lightly doped or unintentionally doped. A crystal plane/doping interface may be provided between the layers grown/doped separately.

The stack may have a vertical sidewall extending in the first direction. On the vertical sidewall, an active layer for defining the active region may be formed. The active layer may be formed through the epitaxial growth, and thus a thickness of the active layer and a thickness of the channel region thus defined may be well controlled. In addition, a material of the active layer may be appropriately selected according to the application. Since a next process (especially an etching process) is mainly performed for the above-mentioned stack, there may be a less restriction on a selection of the material of the active layer.

A dopant in the first source/drain defining layer, a dopant in the body contact defining layer and a dopant in the second source/drain defining layer may be respectively driven into corresponding portions of the active layer by, for example, a heat treatment, so as to form the lower source/drain region, the body contact region and the upper source/drain region, respectively. The resulting lower source/drain region, body contact region, and upper source/drain region may be self-aligned with the first source/drain defining layer, the body contact defining layer, and the second source/drain defining layer, respectively.

A gate stack including of a gate dielectric layer and a gate conductor layer may be formed on a side of the active layer facing away from the above-mentioned stack in a second direction intersecting (e.g., perpendicular to) the first direction. The gate stack may at least overlap with the channel region, so as to effectively control the channel region.

In addition, the gate stack may be formed through the self-align process. For example, the first channel defining layer and the second channel defining layer may be relatively recessed at the vertical sidewall by selective etching, so as to define a space for accommodating (at least a part of the end portion of) the gate stack, and then form an active layer. A dummy gate may be formed to maintain the space thus defined.

On a side of the active layer facing away from the gate stack, i.e. the side where the above-mentioned stack is located, some contact portions may be fabricated, such as an upper source/drain region contact portion to the upper source/drain region, a body contact portion to the body contact region (and optionally, a contact portion to a well region in the substrate).

The present disclosure may be presented in various forms, some examples of which will be described below. In the following description, a selection of various materials is involved. In the selection of materials, in addition to a function of the material (for example, a semiconductor material may be used to form the active region, a dielectric material may be used to form an electrical isolation, and a conductive material may be used to form an electrode, an interconnection structure, and the like), the etching selectivity is also considered. In the following description, the required etching selectivity may or may not be indicated. It should be clear to those skilled in the art that when etching a material layer is mentioned below, if it is not mentioned or shown that other layers are also etched, then the etching may be selective, and the material layer may have an etching selectivity with respect to other layers exposed to the same etching recipe.

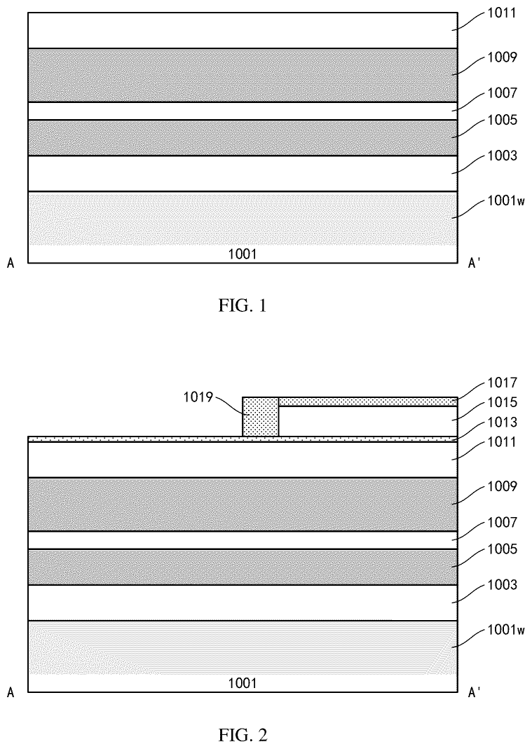

FIG. 1 to FIG. 12 show schematic diagrams of some stages in a process of manufacturing a semiconductor device according to an embodiment of the present disclosure.

As shown in FIG. 1, a substrate 1001 is provided. The substrate 1001 may be in various forms, including but not limited to a bulk semiconductor material substrate such as a bulk Si substrate, a semiconductor-on-insulator (SOI) substrate, a compound semiconductor substrate such as a SiGe substrate, and the like. In the following description, for convenience of explanation, the bulk Si substrate such as a Si wafer is taken as an example for description.

In the substrate 1001, a well region 1001w may be formed by, for example, ion implantation. The well region 1001w may contain a dopant with a certain type of conductivity (for example, for an n-type device, a p-type conductivity; for a p-type device, an n-type conductivity) and a certain concentration such as about 1E17 cm⁻³ to 1E19 cm⁻³. There are a plurality of ways to provide such well region in the art, which will not be described in detail here.

On the substrate 1001, a first source/drain defining layer 1003, a first channel defining layer 1005, a body contact defining layer 1007, a second channel defining layer 1009, and a second source/drain defining layer 1011 may be sequentially formed by, for example, epitaxial growth. The layers grown on the substrate 1001 may be single crystal semiconductor layers and may have crystalline interfaces therebetween.

The first source/drain defining layer 1003 and the second source/drain defining layer 1011 may then define positions of the source/drain regions, with their respective thicknesses ranging from about 20 nm to 200 nm. The first source/drain defining layer 1003 and the second source/drain defining layer 1011 may be doped with a dopant of a certain conductivity type (for example, for the n-type device, the n-type conductivity type; for the p-type device, the p-type conductivity type) and a certain concentration such as about 1E18 cm⁻³ to 1E21 cm⁻³ by, for example, in-situ doping during growth.

The body contact defining layer 1007 may then define a position of the body contact, with a thickness of about 2 nm to 100 nm. In order to optimize the device performance, such as adjusting the threshold voltage (Vt), the body contact defining layer 1007 may be doped with a dopant of a certain conductivity type (for example, for the n-type device, the p-type conductivity type; for the p-type device, the n-type conductivity type) and a certain concentration such as about 1E17 cm⁻³ to 1E20 cm⁻³ by, for example, in-situ doping during growth.

The first channel defining layer 1005 and the second channel defining layer 1009 may then define a position of the channel region along with the body contact defining layer 1007, and their respective thicknesses may be about 5 nm to 50 nm. In order to optimize the device performance such as adjusting Vt, at least one of the first channel defining layer 1005 and the second channel defining layer 1009 may be doped by, for example, in situ doping during growth.

Since the layers are doped separately, a doping concentration interface may be provided therebetween.

The first source/drain defining layer 1003, the first channel defining layer 1005, the body contact defining layer 1007, the second channel defining layer 1009, and the second source/drain defining layer 1011 may include various suitable semiconductor materials, e.g., an elemental semiconductor material such as Si or Ge, a compound semiconductor material such as SiGe or the like. In order to provide a proper etching selectivity in subsequent processes, an etching selectivity may be provided between layers adjacent to each other among the layers. For example, in a case that the substrate 1001 is a Si wafer, the first source/drain defining layer 1003, the body contact defining layer 1007, and the second source/drain defining layer 1011 may include Si, while the first channel defining layer 1005 and the second channel defining layer 1009 may include SiGe (for example, an atomic percentage of Ge is about 10% to 30%).

For the convenience of patterning, as shown in FIG. 2, an etch stop layer 1013, a mandrel layer 1015, and a hard mask layer 1017 may be sequentially formed on the stack of semiconductor layers described above by, for example, deposition. For example, the etch stop layer 1013 may include an oxide (such as silicon oxide), with a thickness of about 2 nm to 15 nm. The mandrel layer 1015 may include amorphous silicon or polycrystalline silicon, with a thickness of about 50 nm to 200 nm. The hard mask layer 1017 may include a nitride (such as silicon nitride), with a thickness of about 20 nm to 100 nm.

A photoresist (not shown) may be formed on the hard mask layer 1017 and patterned by photolithography to have a vertical sidewall extending in the first direction (a direction perpendicular to the paper plane in FIG. 2). The hard mask layer 1017 and the mandrel layer 1015 may be selectively etched sequentially with the patterned photoresist as an etching mask by, for example, Reactive Ion Etching (RIE), so that the pattern of the photoresist may be transferred to the hard mask layer 1017 and the mandrel layer 1015. RIE may be performed in the vertical direction. Etching may stop at the etch stop layer 1011. Then, the photoresist may be removed. Accordingly, the mandrel layer 1015 (and the hard mask layer 1017) may have the vertical sidewall extending in the first direction.

A spacer 1019 may be formed on the sidewall. For example, a layer of nitride having a thickness of about 5 nm to 50 nm may be deposited in a substantially conformal manner, and then anisotropic etching such as RIE (which may stop at the etch stop layer 1013) may be performed on the deposited nitride layer in the vertical direction to remove a lateral extension portion of the deposited nitride layer and leave a vertical extension portion of the deposited nitride layer, so as to obtain the spacer 1019. The spacer 1019 may then be used to at least partially define a size of the upper source/drain region contact layer.

In FIG. 2, a possible curved shape of a top end of the spacer 1019 due to RIE is not shown for convenience. Such curved shape (if any) does not affect the subsequent processes. The same applies to the spacer illustrated below.

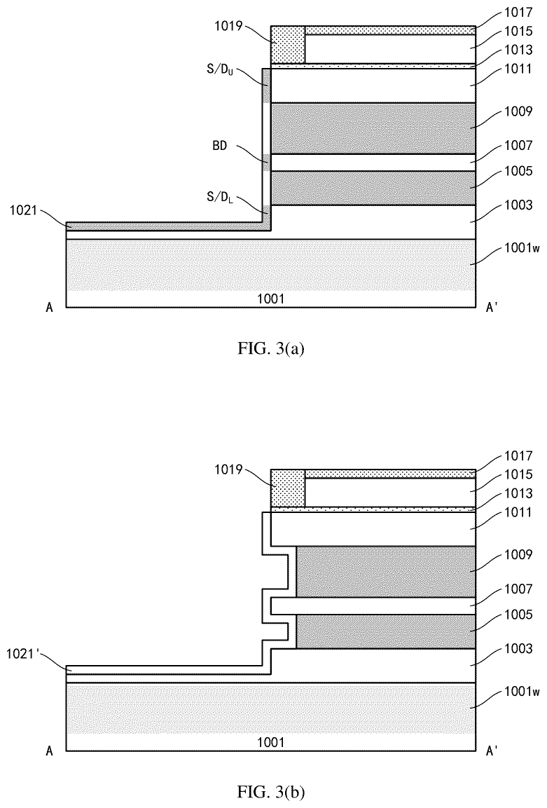

As shown in FIG. 3(a), (the etch stop layer 1013 and) the second source/drain defining layer 1011, the second channel defining layer 1009, the body contact defining layer 1007, the first channel defining layer 1005, and the first source/drain defining layer 1003 may be selectively etched sequentially with the spacer 1019 and the hard mask layer 1017 as the etching masks by, for example, RIE, so that the stack of semiconductor layers may have a vertical sidewall extending in the first direction as a growth surface of the active layer. The RIE may proceed in the vertical direction, and may not proceed into a bottom surface of the first source/drain defining layer 1003, but stop in the first source/drain defining layer 1003.

On the vertical sidewall of the stack of semiconductor layers, an active layer 1021 may be formed by, for example, selective epitaxial growth. The active layer 1021 may include various suitable semiconductor materials, e.g., the elemental semiconductor material such as Si, the compound semiconductor material such as an III-V group compound semiconductor, SiC, or the like. The active layer 1021 may then define the channel region, with a thickness of, for example, about 3 nm to 20 nm. According to embodiments of the present disclosure, the thickness of the active layer 1021 (and thus the channel region) may be determined by the epitaxial growth process, thereby better controlling the thickness of the channel region and reducing a thickness fluctuation.

A dopant may be driven into the active layer 1021 from the first source/drain defining layer 1003 and the second source/drain defining layer 1011 through annealing, so that doping regions as a lower source/drain region S/D_{L} and an upper source/drain region S/D_{U} are formed in regions in the active layer 1021 which correspond to the first source/drain defining layer 1003 and the second source/drain defining layer 1011, respectively. A dopant (if exists) is driven into the active layer 1021 from the body contact defining layer 1017, so that a doping region as a body contact region BD is formed in a region in the active layer 1021 corresponding to the body contact defining layer 1017. In addition, if there are dopants present in the first channel defining layer 1005 and/or the second channel defining layer 1009, these dopants may also be driven into the corresponding regions in the active layer 1021 during the annealing process.

Here, the condition (such as annealing time) of the annealing process may be controlled, so that a diffusion degree of the dopant from the first source/drain defining layer 1003, the second source/drain defining layer 1011, and the body contact defining layer 1017 to the active layer 1021 may be equivalent to the thickness of the active layer 1021. In this way, the positions of the lower source/drain region S/D_{L}, the body contact region BD, and the upper source/drain region S/D_{U} in the vertical direction may be defined by the first source/drain defining layer 1003, the body contact defining layer 1007, and the second source/drain defining layer 1011, respectively. Correspondingly, the position of the channel region between the lower source/drain region S/D_{L} and the upper source/drain region S/D_{U} may be defined by the first channel defining layer 1005, the body contact defining layer 1007, and the second channel defining layer 1009. That is, a length of the channel region may be determined by thicknesses of the first channel defining layer 1005, the body contact defining layer 1007, and the second channel defining layer 1009. The thicknesses of the first channel defining layer 1005, the body contact defining layer 1007, and the second channel defining layer 1009 may be determined by the epitaxial growth process, and thus the length of the channel region may be better controlled.

In the example, the upper source/drain region S/D_{U} and lower source/drain region S/D_{L} may have a same conductivity type, and the body contact region BD may have a different conductivity type. However, the present disclosure is not limited to this. For example, the upper source/drain region S/D_{U} and the lower source/drain region S/D_{L} may have different conductivity types (and thus form, for example, a tunneling device), while the body contact region BD may have a different conductivity type from one of them.

In FIG. 3(a), for ease of understanding, the lower source/drain region S/D_{L}, the body contact region BD, and the upper source/drain region S/D_{U} are shaded. In the following drawings, these doped regions will not be shown separately for convenience and clarity.

According to embodiments of the present disclosure, a size of the body contact region BD and a relative position of the body contact region BD in the vertical direction may be adjusted by controlling the thickness of at least one of the first channel defining layer 1005, the body contact defining layer 1007, and the second channel defining layer 1009. For example, in a case that the thickness of the first channel defining layer 1005 and the thickness of the second channel defining layer 1009 are substantially the same, the body contact region BD may be located at a substantially middle portion of the channel region in the vertical direction. Alternatively, in a case that the thicknesses of the first channel defining layer 1005 and the second channel defining layer 1009 are different from each other, the body contact region BD may be close to the lower source/drain region S/D_{L} in the vertical direction (for example, in a case that the first channel defining layer 1005 is thinner than the second channel defining layer 1009) or close to the upper source/drain region S/D_{U} in the vertical direction (for example, in a case that the first channel defining layer 1005 is thicker than the second channel defining layer 1009).

In the example, the first source/drain defining layer 1003 has a part that extends beyond the region defined by the spacer 1019 and the hard mask layer 1017, and thus the active layer 1021 also grows on this part to have a lateral extension portion. The lateral extension portion of the active layer 1021 is doped due to the diffusion of the dopant in the first source/drain defining layer 1003 below during the annealing process, and thus may be used as a part of the lower source/drain region S/D_{L}. The lateral extension portion of the lower source/drain region S/D_{L} may help to land a subsequently formed contact portion to the lower source/drain region S/D_{L} thereon.

According to another embodiment of the present disclosure, in order to achieve a self-aligning gate, as shown in FIG. 3(b), after the vertical sidewall is patterned in the stack of semiconductor layers by using the spacer 1019 and the hard mask layer 1017 as described above in connection with FIG. 3(a), the first channel defining layer 1005 and the second channel defining layer 1009 may be relatively recessed in a lateral direction through selective etching. In order to control an etching depth, Atomic Layer Etching (ALE) may be adopted.

Here, due to etching selectivity, the body contact defining layer 1007 protrudes with respect to the first channel defining layer 1005 and the second channel defining layer 1009. However, the present disclosure is not limited to this. For example, by selecting proper materials, an etching recipe that may selectively etch the first channel defining layer 1005, the second channel defining layer 1009, and the body contact defining layer 1007 (with respect to the first source/drain defining layer 1003 and the second source/drain defining layer 1011) may be used, so that the first channel defining layer 1005, the second channel defining layer 1009, and the body contact defining layer 1007 may be relatively recessed, so as to define the space for the gate stack.

Then, an active layer 1021′ may be similarly grown and a dopant may be driven into the active layer 1021′. Regarding the active layer 1021′ and the dopant driving-in, please refer to the above description of the active layer 1021 and the dopant driving-in, except that the active layer 1021′ may have a curved shape due to the relative recess of the first channel defining layer 1005 and the second channel defining layer 1009.

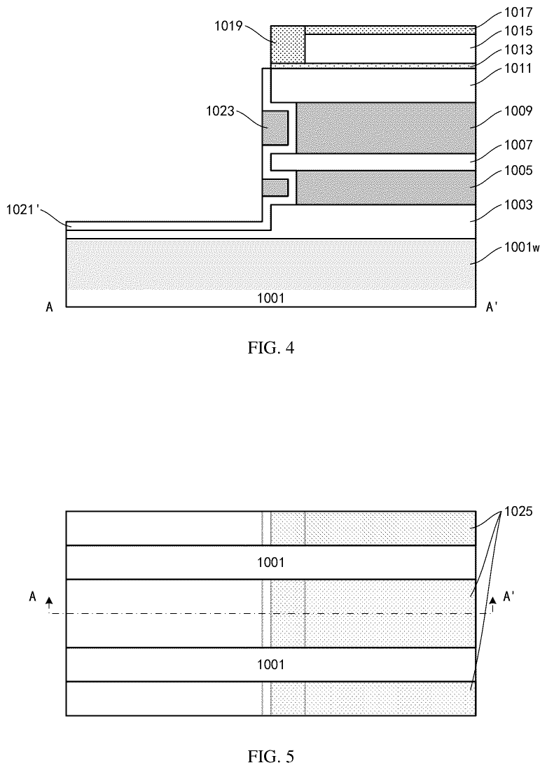

In the recesses at the end portions of the first channel defining layer 1005 and the second channel defining layer 1009 (and optionally the body contact defining layer 1007), as shown in FIG. 4, a dummy gate 1023 may be formed by, for example, deposition and RIE in the vertical direction. Considering the etching selectivity, the dummy gate 1023 may include, for example, SiC.

Hereinafter, the embodiment of FIG. 3(a) will be mainly described as an example. These descriptions also apply generally to the embodiment of FIG. 3(b), and a separate description of the embodiment of FIG. 3(b) will be provided where necessary.

At this point, the stack of semiconductor layers and the active layers 1021 and 1021′ formed on the vertical sidewall thereof may continuously extend in the first direction. As shown in FIG. 5, a photoresist 1025 may be formed and patterned as a strip opening extending in a second direction (a horizontal direction of the paper plane in a top view of FIG. 5) that intersects (for example, perpendicular to) the first direction (a vertical direction of the paper plane in the top view of FIG. 5). The stack of semiconductor layers and the active layers 1021 and 1021′ may be divided into different sections arranged in the first direction by, for example, RIE in the vertical direction based on the photoresist 1025, so as to define the active regions of different devices. Afterwards, the photoresist 1025 may be removed. RIE may proceed into the substrate 1001. Trenches (regions divided between the sections) thus formed may be filled with a dielectric material such as an oxide, so as to form an isolation between devices, such as shallow trench isolation (STI). In the top view of FIG. 5, a cut-off position line AA′ of a cross-sectional view in other figures is also schematically shown.

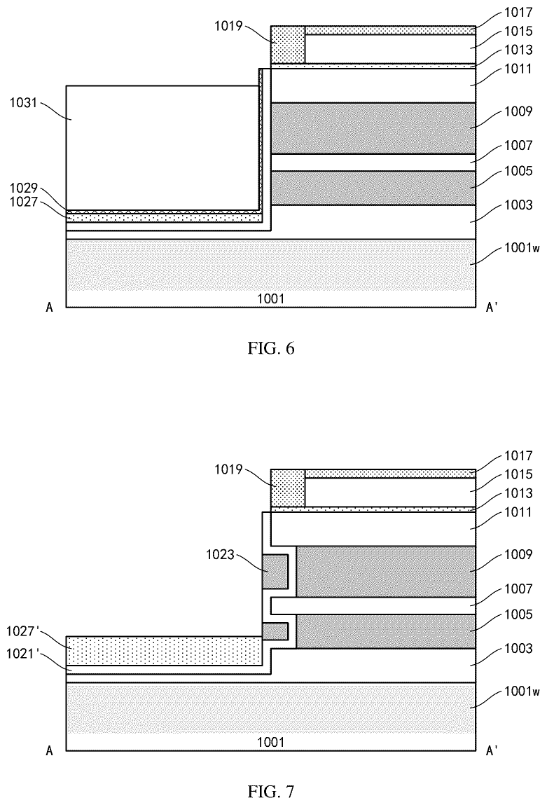

In order to reduce the overlap with the source/drain region by allowing the subsequently formed gate stack to primarily overlap with the channel region, as shown in FIG. 6, an isolation layer 1027 may be formed first. For example, an oxide layer that completely covers the formed structure on the substrate 1001 may be formed on the substrate 1001 by deposition, and a planarization process such as Chemical Mechanical Polishing (CMP) may be performed on the deposited oxide layer (CMP may stop at the hard mask layer 1017 and/or spacer 1019 of nitride), and then the isolation layer 1027 may be formed by etching back the planarized oxide layer by, for example, RIE. A thickness of the isolation layer 1027 allows a region (i.e., a region corresponding to the first channel defining layer 1005, the body contact defining layer 1007, and the second channel defining layer 1009) of the channel region in the active layer 1021 to be exposed, for example, a top surface of the isolation layer 1027 may not be higher than, preferably (slightly) lower than, the bottom surface of the first channel defining layer 1005.

A gate stack may be formed on the isolation layer 1027. The gate stack may include a gate dielectric layer 1029 and a gate conductor layer 1031. For example, the gate dielectric layer 1029 may include a high k dielectric (such as HfO₂) layer with a thickness of about 1 nm to 10 nm formed by, for example, deposition. The gate dielectric layer 1029 may be formed in a substantially conformal manner. Before forming the gate dielectric layer 1029, a thin interface layer, such as an oxide of about 0.3 nm to 2 nm, may be formed through oxidation or deposition. The gate conductor layer 1031 may include a work function adjustment layer such as TiN, TiAlN, a material containing Ta or La, or the like, and may also include a conductive material layer such as W or the like as needed. The gate conductor layer 1031 may be etched back, so that a top surface of the gate conductor layer 1031 may be higher than the top surface of the second channel defining layer 1009 to ensure overlap with the channel region (but should not be too high to reduce the overlap with the upper source/drain region S/D_{U} corresponding to the second source/drain defining layer 1011).

The gate stack (1029/1031) formed in this way is not self-aligned, and thus may have some overlap with the lower source/drain region S/D_{L} and/or the upper source/drain region S/D_{U}.

In another embodiment described in combination with FIG. 3(b) and FIG. 4 above, the gate stack may be self-aligned with the channel region in the active layer 1021′.

For example, as shown in FIG. 7, an isolation layer 1027′ may be formed as the isolation layer 1027 is formed described above. A main difference between the isolation layer 1027′ and the isolation layer 1027 is that: a top surface of the isolation layer 1027′ may be higher than the bottom surface of the first channel defining layer 1005. This is because the lower end of the channel region is not blocked by the isolation layer 1027′ (although the top surface thereof is high) due to the presence of the dummy gate 1023.

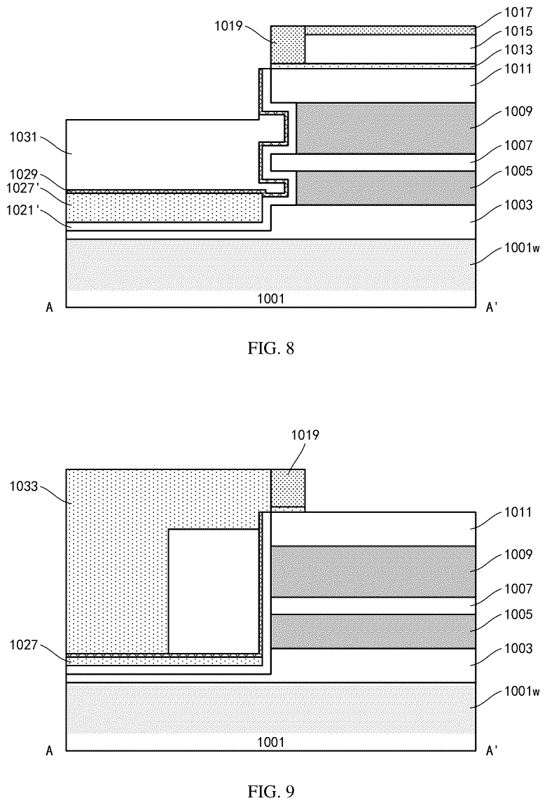

Then, as shown in FIG. 8, the dummy gate 1023 may be removed by selective etching. A gate stack (1029/1031) may be formed as described above on the isolation layer 1027′. The formed gate stack may enter the space previously occupied by the dummy gate 1023, so as to overlap with the channel region in the active layer 1021′.

In this example, the gate conductor layer 1031 may be etched back to have a top surface lower than the top surface of the second channel defining layer 1009. Additionally, due to the setting of the top surface of the isolation layer 1027′ described above, the end portion of the gate stack close to the active layer 1021′ is defined by the dummy gate 1023, and the position of the dummy gate 1023 is defined by the first channel defining layer 1005 and the second channel defining layer 1009 themselves. Therefore, the gate stack may be self-aligned with the channel region in the active layer 1021′.

Next, various contact portions may be fabricated. According to embodiments of the present disclosure, in addition to the contact portions to the source/drain region and gate stack of the device, the contact portion to the body contact region may also be fabricated.

For example, as shown in FIG. 9, a shielding layer 1033 may be formed to shield the gate stack. For example, an oxide layer that completely covers the formed structure on the substrate 1001 may be formed on the substrate 1001 by deposition, and a planarization process such as CMP may be performed on the deposited oxide layer (CMP may stop at the hard mask layer 1017 and/or spacer 1019 of nitride), so as to form the shielding layer 1033. Before forming the shielding layer 1033, a part of the gate conductor layer 1031 may be removed by selective etching, so as not to affect the contact portion to the first source/drain defining layer 1003 that is subsequently formed below the gate conductor layer 1031.

The hard mask layer 1017 may be removed by selective etching such as RIE in the vertical direction, so as to expose the mandrel layer 1015. Here, the spacer 1019, which is also the nitride like the hard mask layer 1017, may be retained due to a thicker thickness. The mandrel layer 1015 and the etch stop layer 1013 may be sequentially removed by selective etching such as RIE in the vertical direction, so as to expose the second source/drain defining layer 1011.

In this way, the stack of semiconductor layers is exposed on the side of the active layer 1021 facing away from the gate stack. A landing pad of the contact portion may be formed in the exposed stack of semiconductor layers.

Here, the spacer 1019 covers a part of the second source/drain defining layer 1011, and the part of the second source/drain defining layer 1011 covered by the spacer 1019 may define a landing pad of the contact portion to the upper source/drain region S/D_{U}.

Next, a landing pad of the contact portion to the body contact region BD may be defined.

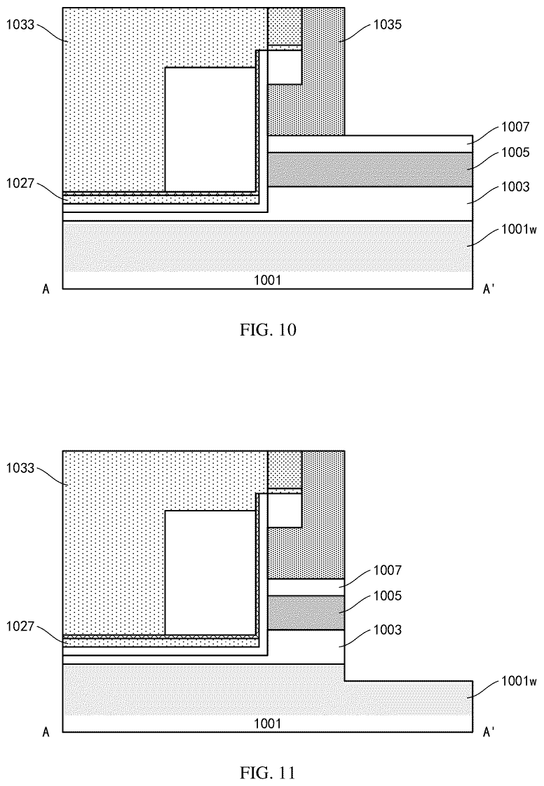

For example, as shown in FIG. 10, the second source/drain defining layer 1011 may be etched with the spacer 1019 as an etching mask by, for example, RIE in the vertical direction, so as to expose the second channel defining layer 1009. The second channel defining layer 1009 may be removed by selective etching. Due to the etching selectivity of the second channel defining layer 1009 (in the example, SiGe) with respect to the second source/drain defining layer 1011 and the body contact defining layer 1007 (in the example, Si), the second source/drain defining layer 1011 and the body contact defining layer 1007 may be substantially unaffected.

Accordingly, the body contact defining layer 1007 may protrude with respect to the second source/drain defining layer 1011 above, and a protruding part of the body contact defining layer 1007 may define the landing pad of the contact portion to the body contact region BD.

According to some embodiments, a contact portion to the well region 1001w in the substrate 1001 may also be fabricated. In this case, in order to expose the well region 1001w below, a spacer 1035 may be formed on the body contact defining layer 1007, which is similar to using the spacer 1019 to define the landing pad of the contact portion to the upper source/drain region S/D_{U}, so as to define a landing pad of the contact portion to the body contact region BD. The spacer 1035 may be formed by the process for the spacer 1019 described above. Considering the etching selectivity, the spacer 1035 may include SiC. A part of the body contact defining layer 1007 covered by the spacer 1035 may define the landing pad of the contact portion to the body contact region BD. Here, the spacer 1035 may further enter a space originally occupied by the second channel defining layer 1009 between the second source/drain defining layer 1011 and the body contact defining layer 1007.

Then, as shown in FIG. 11, the body contact defining layer 1007, the first channel defining layer 1005, and the first source/drain defining layer 1003 may be sequentially etched with the spacer 1035 (and the spacer 1019 and the shielding layer 1033) as an etching mask by, for example, RIE in the vertical direction, so as to expose the well region 1001w. In this example, since both the first source/drain defining layer 1003 and the substrate 1001 include Si, the etching of the first source/drain defining layer 1003 may proceed into the well region 1001w.

In addition, the first channel defining layer 1005 may be removed by selective etching.

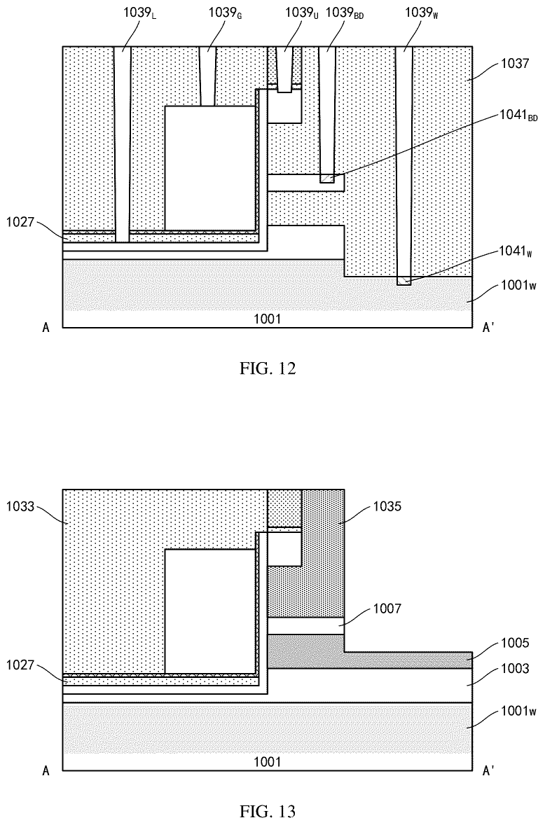

As shown in FIG. 12, an interlayer dielectric layer 1037 may be formed on the substrate. For example, an oxide layer that completely covers the formed structure on the substrate 1001 may be formed on the substrate 1001 by deposition, and a planarization process such as CMP may be performed on the deposited oxide layer (CMP may stop at the spacer 1019 of nitride), so as to form the interlayer dielectric layer 1037. Here, the shielding layer 1033, which is also an oxide, may become a part of the interlayer dielectric layer 1037 and is no longer labeled separately. Even if the shielding layer 1033 includes a different dielectric material, the shielding layer 1033 may still serve as a part of the interlayer dielectric layer; alternatively, the shielding layer 1033 may be removed and replaced by the interlayer dielectric layer 1037. In addition, the spacer 1035 may be retained as a part of the interlayer dielectric layer, or may be removed and replaced by the interlayer dielectric layer 1037. FIG. 12 shows a case that the spacer 1035 is removed.

In the interlayer dielectric layer 1037, a contact portion 1039L to the lower source/drain region S/D_{L}, a contact portion 1039_{U} to the upper source/drain region S/D_{U}, a contact portion 1039_{BD} to the body contact region BD, a contact portion 1039_{G} to the gate stack (specifically, the gate conductor layer 1031), and a contact portion 1039_{W} to the well region 1001w may be formed. The contact portion 1039_{L} is landed on a part of the first source/drain defining layer 1003 that protrudes with respect to the upper conductive layer (e.g., the gate conductor layer 1031). The contact portion 1039_{U} is landed on (a part defined by the spacer 1019) the second source/drain defining layer 1011 (the second source/drain defining layer 1011 achieves an electrical contact of the contact portion 1039_{U} to the upper source/drain region S/D_{U}, and thus may be referred to as the upper source/drain region contact layer). The contact portion 1039_{BD} is landed on (a part defined by the spacer 1035) the body contact defining layer 1007 (the body contact defining layer 1007 achieves the body contact of the contact portion 1039_{BD} to the active region, and thus may be referred to as the body contact layer). These contact portions may be formed by etching holes in the interlayer dielectric layer 1037 and filling the holes with a conductive material such as a metal.

In addition, considering the relatively light doping of the body contact defining layer 1007 and the well region 1001w, in order to reduce the contact resistance, ion implantation may be performed via the holes before filling the holes with the conductive material, so as to form relatively high doping (with the same conductivity type as the body contact defining layer 1007 and the well region 1001w) contact regions 1041_{BD} and 1041_{W} in the body contact defining layer 1007 and the well region 1001w, respectively. The contact portions 1039_{BD} and 1039_{W} may be electrically connected to the body contact region BD and the well region 1001w through the contact regions 1041_{BD} and 1041_{W}, respectively.

As shown in FIG. 12, the semiconductor device according to the embodiment may include a vertical active region defined by the active layer 1021. The vertical active region may include the lower source/drain region S/D_{L}, the upper source/drain region S/D_{U}, and the channel region between the lower source/drain region S/D_{L} and the upper source/drain region S/D_{U}. The thickness and length of the channel region may be controlled through epitaxial growth described above, and the epitaxial growth may achieve a control accuracy even of monoatomic layers.

There may be a body contact region BD in the channel region. The body contact region BD may only occupy a part of the channel region in the vertical direction. As described above, the body contact region BD may be located in the substantially middle portion of the channel region in the vertical direction, or may be biased towards the lower source/drain region S/D_{L} or the upper source/drain region S/D_{U}. A body bias may be applied to the active region through the contact portion 1039_{BD} (via the body contact region BD) to reduce the floating-body effect. The position and size of the body contact region BD in the vertical direction may be controlled by epitaxial growth, and the epitaxial growth may achieve the control accuracy even of monoatomic layers.

The remaining part of the channel region except for the body contact region BD may also be doped (for example, diffusion from the first channel defining layer 1005 and/or the second channel defining layer 1009), and the doping characteristic may be different from the doping characteristic in the body contact region BD. For example, the doping concentration in the body contact region BD may be higher than the doping concentration (defined by diffusion from the first channel defining layer 1005) in the region between the body contact region BD and the lower source/drain region S/D_{L} and/or the doping concentration (defined by diffusion from the second channel defining layer 1009) in the region between the body contact region BD and the upper source/drain region S/D_{U}.

The gate stack (1029/1031) may be disposed on a side (left side in FIG. 12) of the vertical active region in the second direction, facing the vertical active region and overlapping with the channel region therein. The gate stack may be self-aligned with the channel region. In this case, an end portion of the gate stack close to the vertical active region may have an upper protrusion portion, a lower protrusion portion, and a recess portion between the upper protrusion portion and the lower protrusion portion. The body contact defining layer 1007 may be self-aligned with the recess portion of the end portion of the gate stack.

The body contact defining layer 1007 (or the body contact layer) may be provided on the side (right side in FIG. 12) of the vertical active region facing away from the gate stack, and the contact portion 1039_{BD} may be landed on the body contact defining layer 1007. The body contact region BD may be self-aligned with the body contact layer.

In the above-mentioned embodiments, a body bias and a well bias may be applied via the contact portions 1039_{BD} and 1039_{W}, respectively. However, the present disclosure is not limited to this.

FIG. 13 to FIG. 17 show schematic diagrams of some stages in a process of manufacturing a semiconductor device according to another embodiment of the present disclosure.

After forming the spacer 1035 as described above in combination with FIG. 10, as shown in FIG. 13, the body contact defining layer 1007 may be selectively etched with the spacer 1035 (and the spacer 1019 and the shielding layer 1033) as an etching mask by, for example, RIE in the vertical direction. FIG. 13 shows that the first channel defining layer 1005 is also partially etched, which is to ensure that the subsequently formed protective layer may fully cover the sidewall of the body contact defining layer 1007.

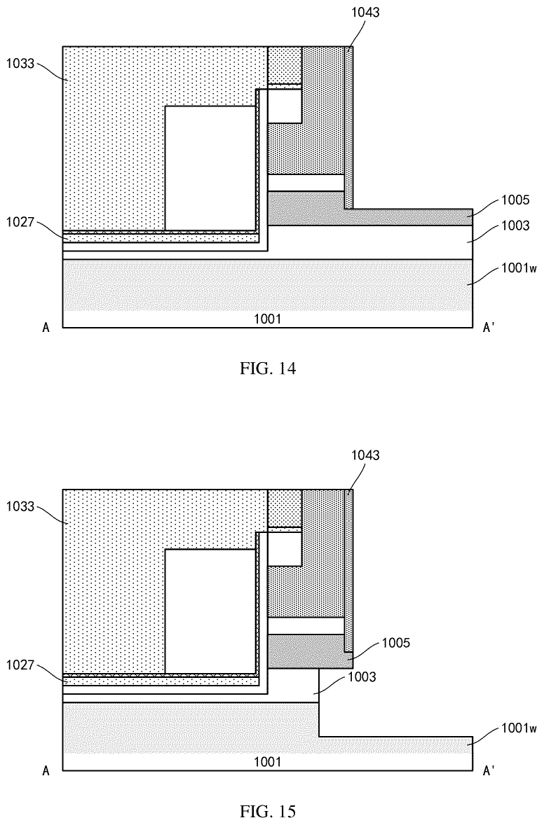

As shown in FIG. 14, a protective layer 1043 in a form of spacer may be formed through the spacer formation process, so as to shield the sidewall of the body contact defining layer 1007. Considering the etching selectivity and subsequent removal of the spacer 1035 and the protective layer 1043, the protective layer 1043 may include SiC like the spacer 1035.

As shown in FIG. 15, the first channel defining layer 1005 may be selectively etched with the protective layer 1043 and the spacer 1035 (and the spacer 1019 and the shielding layer 1033) as etching masks by, for example, RIE in the vertical direction, so as expose the first source/drain defining layer 1003. The first source/drain defining layer 1003 may be selectively etched to expose the well region 1001w. Unlike the above-mentioned embodiments, the selective etching of the first source/drain defining layer 1003 in this embodiment may cause the first source/drain defining layer 1003 to be recessed with respect to the body contact defining layer 1007. For example, ALE or wet corrosion using TMAH solution may be adopted. Similarly, the substrate 1001, which is also Si, may also be etched here. However, due to the presence of the protective layer 1043 and the first channel defining layer 1005, the body contact defining layer 1007 may be unaffected.

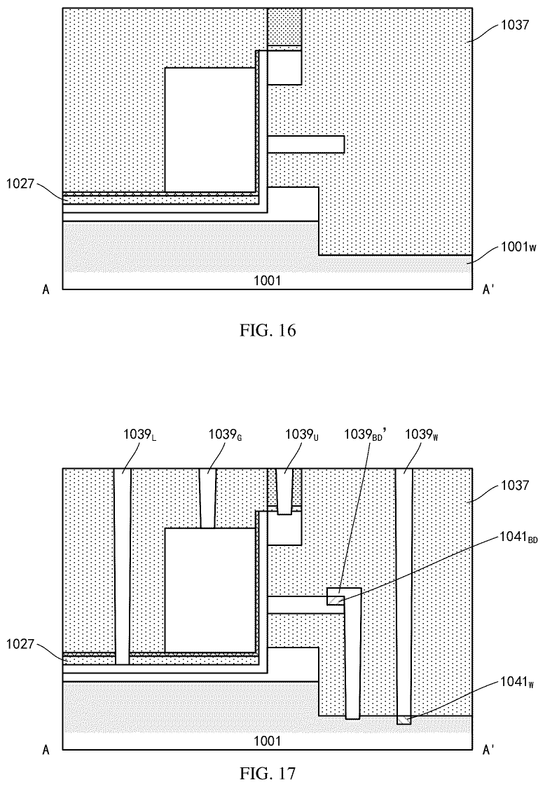

Then, as shown in FIG. 16, the first channel defining layer 1005 of SiGe, the protective layer 1043 of SiC and the spacer 1035 of SiC may be removed by selective etching, respectively. The interlayer dielectric layer 1037 may be formed as described above in combination with FIG. 12.

As shown in FIG. 17, various contact portions may be formed in the interlayer dielectric layer 1037. The difference from the above-mentioned embodiments is that the body contact portion 1039_{BD′} may extend downwards into the well region 1001w. The body bias may be applied via the contact portion 1039_{W}, the well region 1001w, and the body contact portion 1039_{BD′}.

The semiconductor device according to embodiments of the present disclosure may be applied to various electronic apparatuses. For example, an integrated circuit (IC) may be formed based on such semiconductor devices, and an electronic apparatus may be constructed in this way. Accordingly, the present disclosure further provides an electronic apparatus including the semiconductor device described above. The electronic apparatus may further include a display screen cooperating with the integrated circuit, a wireless transceiver cooperating with the integrated circuit, and other components. The electronic apparatus may include, for example, a smart phone, a personal computer (PC), a tablet computer, an artificial intelligence apparatus, a wearable apparatus, a mobile power supply, an automotive electronic apparatus, a communication apparatus, or an Internet of Things (IoT) apparatus.

According to embodiments of the present disclosure, a method of manufacturing a system on chip (SoC) is further provided. This method may include the above-mentioned method. Specifically, a variety of devices may be integrated on the chip, at least some of which are manufactured according to the method of the present disclosure.

In the above descriptions, technical details such as patterning and etching of each layer have not been described in detail. However, those skilled in the art should understand that various technical means may be used to form layers, regions, etc. of desired shapes. In addition, in order to form the same structure, those skilled in the art may further design a method that is not completely the same as the method described above. In addition, although the various embodiments are described above separately, this does not mean that the measures in the various embodiments may not be advantageously used in combination.

Embodiments of the present disclosure have been described above. However, the embodiments are for illustrative purposes only, and are not intended to limit the scope of the present disclosure. The scope of the present disclosure is defined by the appended claims and their equivalents. Without departing from the scope of the present disclosure, those skilled in the art may make various substitutions and modifications, and these substitutions and modifications should all fall within the scope of the present disclosure.

What is claimed is:

1. A semiconductor device, comprising:
an active region vertically disposed on a substrate with respect to the substrate, wherein the active region comprises a lower source/drain region, an upper source/drain region, and a middle portion which is located between the lower source/drain region and the upper source/drain region and configured to define a channel region;
a gate stack disposed on a first side of the active region in a lateral direction with respect to the substrate, so as to at least overlap with the middle portion of the active region; and
a body contact layer disposed on a second side of the active region opposite to the first side in the lateral direction, so as to overlap with the middle portion of the active region to apply a body bias to the active region,
wherein in a vertical direction with respect to the substrate, a distance between a part of the middle portion of the active region overlapping with the body contact layer and the lower source/drain region is a first spacing distance, and a distance between the part of the middle portion of the active region overlapping with the body contact layer and the upper source/drain region is a second spacing distance.

2. The semiconductor device according to claim 1, wherein the first spacing distance is substantially equal to the second spacing distance.

3. The semiconductor device according to claim 1, wherein the middle portion of the active region comprises a doping region as a body contact region, and the body contact layer is in contact with the body contact region.

4. The semiconductor device according to claim 3, wherein a conductivity type of the body contact region is opposite to a conductivity type of at least one of the lower source/drain region and the upper source/drain region.

5. The semiconductor device according to claim 3, wherein the body contact region is self-aligned with the body contact layer.

6. The semiconductor device according to claim 3, wherein the body contact layer comprises a dopant of a same conductivity type as a dopant in the body contact region.

7. The semiconductor device according to claim 3, wherein the body contact region occupies only a part of the middle portion of the active region in the vertical direction.

8. The semiconductor device according to claim 7, wherein the body contact region and a remaining part of the middle portion of the active region have different doping characteristics.

9. The semiconductor device according to claim 8, wherein a doping concentration in the body contact region is higher than a doping concentration of at least one of a region in the middle portion of the active region between the body contact region and the lower source/drain region and a region in the middle portion of the active region between the body contact region and the upper source/drain region.

10. The semiconductor device according to claim 1, wherein the active region comprises a single crystal semiconductor.

11. The semiconductor device according to claim 1, wherein the body contact layer comprises a single crystal semiconductor.

12. The semiconductor device according to claim 1, further comprising:
a body contact portion to the body contact layer, wherein the body contact portion is configured to receive the body bias,
wherein the body contact layer extends away from the active region in the lateral direction, and the body contact portion is in contact with the body contact layer.

13. The semiconductor device according to claim 12, further comprising:
a contact region in the body contact layer, wherein the contact region is highly doped with respect to other regions in the body contact layer, and the body contact portion is in contact with the contact region.

14. The semiconductor device according to claim 12, further comprising:
an upper source/drain region contact layer disposed on the second side of the active region in the lateral direction, so as to be in contact with the upper source/drain region; and
an upper source/drain region contact portion landed on the upper source/drain region contact layer.

15. The semiconductor device according to claim 14, wherein the upper source/drain region contact layer comprises a single crystal semiconductor.

16. The semiconductor device according to claim 14, wherein the upper source/drain region is self-aligned with the upper source/drain region contact layer.

17. The semiconductor device according to claim 14, wherein the upper source/drain region contact layer comprises a dopant of a same conductivity type as the upper source/drain region.

18. The semiconductor device according to claim 14, wherein a spacing between the upper source/drain region contact layer and the body contact layer in the vertical direction is substantially uniform.

19. The semiconductor device according to claim 14,
wherein the body contact layer extends beyond the upper source/drain region contact layer in the lateral direction, and
wherein the body contact portion is landed on a part of the body contact layer extending beyond the upper source/drain region contact layer.

20. The semiconductor device according to claim 12, further comprising:
a well region in the substrate; and
a well region contact portion to the well region,
wherein the body contact portion extends to the well region.

21. The semiconductor device according to claim 1, wherein the active region is defined by a semiconductor layer of single crystal.

22. The semiconductor device according to claim 21, wherein the semiconductor layer is in a form of a nanosheet or a nanowire.

23. The semiconductor device according to claim 21, wherein the semiconductor layer comprises a vertical extension portion extending in the vertical direction to provide the active region and a lateral extension portion extending from a lower end of the vertical extension portion on the first side, and the semiconductor device further comprises:
a lower source/drain region contact portion to the lower source/drain region, wherein the lower source/drain region contact portion is landed on the lateral extension portion of the semiconductor layer.

24. The semiconductor device according to claim 23, further comprising:
a lower source/drain region defining layer extending from below the lateral extension portion of the semiconductor layer to a surface of the semiconductor layer on the second side.

25. The semiconductor device according to claim 24, wherein the lower source/drain region is self-aligned with a part of the lower source/drain region defining layer on the second side.

26. The semiconductor device according to claim 24, wherein the lower source/drain region defining layer comprises a dopant of a same conductivity type as the lower source/drain region.

27. The semiconductor device according to claim 24, wherein the lower source/drain region defining layer comprises a single crystal semiconductor.

28. The semiconductor device according to claim 24, wherein a spacing between the lower source/drain region defining layer and the body contact layer in the vertical direction is substantially uniform.

29. The semiconductor device according to claim 1, wherein the gate stack is self-aligned with the middle portion of the active region.

30. The semiconductor device according to claim 29, wherein an end portion of the gate stack close to the active region has a recess, and the body contact layer is self-aligned with the recess.

31. A method of manufacturing a semiconductor device, comprising:
providing, on a substrate, a stack of a first source/drain defining layer, a first channel defining layer, a body contact defining layer, a second channel defining layer, and a second source/drain defining layer;
forming an active layer on a vertical sidewall of the stack extending in a first direction;
respectively driving a dopant in the first source/drain defining layer, a dopant in the body contact defining layer and a dopant in the second source/drain defining layer into corresponding portions of the active layer, so as to form a lower source/drain region, a body contact region and an upper source/drain region respectively;
forming a gate stack on a side of the active layer facing away from the stack in a second direction intersecting the first direction; and
forming a body contact portion to the body contact defining layer.

32. The method according to claim 31, wherein the stack and the active layer are formed through an epitaxial growth process.

33. The method according to claim 31, wherein before forming the active layer, the method further comprises: selectively etching the first channel defining layer and the second channel defining layer at the vertical sidewall, so that the first channel defining layer and the second channel defining layer are relatively recessed,
wherein after forming the active layer, the method further comprises: forming, in the recess, a dummy gate in a space after the active layer is formed, and
wherein the forming the gate stack further comprises: removing the dummy gate.

34. The method according to claim 31, further comprising:
patterning the stack so that the body contact defining layer protrudes with respect to the second source/drain defining layer, and removing the first channel defining layer and the second channel defining layer,
wherein the body contact portion is landed on a part of the body contact defining layer protruding with respect to the second source/drain defining layer.

35. The method according to claim 31, wherein a well region is formed in the substrate, and the method further comprises:
patterning the stack so that the body contact defining layer protrudes with respect to the first source/drain defining layer, and removing the first channel defining layer and the second channel defining layer,
wherein the body contact portion extends from the body contact defining layer to the well region.

36. The method according to claim 31, wherein forming the body contact portion comprises:
forming an interlayer insulation layer on the substrate;
forming a body contact hole in the interlayer insulation layer, so as to expose a part of the body contact defining layer;
injecting a dopant into the exposed part of the body contact defining layer via the body contact hole; and
filling the body contact hole with a conductive material, so as to form the body contact portion.

37. An electronic apparatus, comprising the semiconductor device according to claim 1.

38. The electronic apparatus according to claim 37, wherein the electronic apparatus comprises a smart phone, a personal computer, a tablet computer, an artificial intelligence apparatus, a wearable apparatus, a mobile power supply, an automotive electronic apparatus, a communication apparatus, or an Internet of Things apparatus.
